(19) United States
(12) Patent Application Publication
(10) Pub. No.: US 2025/0085887 A1
(43) Pub. Date: Mar. 13, 2025

(54) INDUCTORS USING NAND LAYERS

(71) Applicant: Micron Technology, Inc., Boise, ID (US)

(72) Inventors: Srivatsan Venkatesan, Gopanpalle (IN); Kaveri Jain, Hyderabad (IN); Salil Shashikant Mujumdar, Nanakaramguda (IN); Rajat Vishnoi, Bangalore (IN); Sushma Dogiparthi, Hyderabad (IN)

(21) Appl. No.: 18/777,273

(22) Filed: Jul. 18, 2024

(30) Foreign Application Priority Data
Sep. 7, 2023 (IN) 202311060184

(51) Int. Cl. G06F 3/06; G11C 16/04

(52) U.S. Cl. CPC G06F 3/0655; G06F 3/061; G06F 3/0679; G11C 16/0483

(57) ABSTRACT

An inductor is formed on an integrated circuit (IC) using one or more structures formed during or in coordination with 3D NAND structure fabrication with one or more modifications. The inductor has a staircase structure, the staircase structure having a plurality of tiers that form steps on one side of the staircase structure. Each tier comprises a conductive layer. The plurality of tiers includes at least a first tier and a second tier. The inductor has a first contact electrically coupling the first tier and the second tier. A first portion of a die is occupied by a memory sub-component comprising at least one three-dimensional (3D) NAND memory component and a second portion of the die is occupied by the inductor.

### PRIORITY APPLICATION

This application claims the benefit of priority to Indian Patent Application Serial Number 202311060184, filed Sep. 7, 2023, which is incorporated herein by reference in its entirety.

### BACKGROUND

Inductors play an important role in power circuits but are largely absent from on-chip integration. Power circuits, such as DC boost converters, DC buck converters, t-coils, among others, frequently make use of inductors. Conventional on-chip inductors are hard to realize due to the large formfactors necessary to achieve requisitely large inductance values and high quality factors (Q factor) for commercial use. Also, the inductor needs multiple levels of metal levels to realize the structure, which adds to manufacturing cost.

In NAND arrays, charge pumps are conventionally used to generate high voltage. These charge pumps are highly inefficient. For example, a charge pump that boosts a 2.5V supply to ˜31V and typically has lower efficiency than a boost converter. These charge pumps are also area inefficient, taking up a large amount of on-chip area.

### BRIEF DESCRIPTION OF THE SEVERAL VIEWS OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

To easily identify the discussion of any particular element or act, the most significant digit or digits in a reference number refer to the figure number in which that element is first introduced.

FIG. 1 illustrates an environment including a memory device, according to some examples.

FIG. 2 illustrates schematic diagrams of an example of a 3D NAND architecture semiconductor memory array, according to some examples.

FIG. 3 illustrates schematic diagrams of an example of a 3D NAND architecture semiconductor memory array, according to some examples.

FIG. 4 illustrates a block diagram of a memory module, according to some examples.

FIG. 5A illustrates an example inductor in a cross-sectional view, according to some examples.

FIG. 5B illustrates an example inductor in a top-down view, according to some examples.

FIG. 6A illustrates an example inductor in a cross-sectional view, according to some examples.

FIG. 6B illustrates an example inductor in a top-down view, according to some examples.

FIG. 6C illustrates example contact straps on tiers of an example inductor, according to some examples.

FIG. 6D illustrates formation of contact straps on tiers of an example inductor, according to some examples.

FIG. 7A illustrates an example NAND plane with an on-chip inductor, according to some examples.

FIG. 7B illustrates an example NAND die, according to some examples.

FIG. 8 is a flow diagram of features of an example method of forming an inductor, according to various embodiments.

### DETAILED DESCRIPTION

Challenges to implementing an on-chip inductor can include achieving a useful inductance density and q-factor. For example, desirable characteristics of an on-chip inductor include an inductance density on the order of 100's of nH per square millimeter, and a large q-factor. In an example, a useful on-chip inductor can have a low internal resistance to achieve a high q-factor.

In various examples, an on-chip inductor is formed using similar structures used to implement NAND memory. NAND flash memory provides a staircase and pillar-like structure. A solenoid inductor can be formed using, for example, these NAND structures with one or more modifications. The solenoid inductor using NAND structures has high inductance density.

The term “solenoid” is used herein and should be recognized by one of ordinary skill in the art to represent helical and helical-like electromagnets. An example of a solenoid is an electromechanically inductive wire wound around an armature to form a round coil. Should the same wire be wound into a coil with right angles forming a rectangular cross-section, the resultant electromagnet is also a solenoid.

The following detailed description refers to the accompanying drawings that show, by way of illustration, various examples that can be implemented. These examples are described in sufficient detail to enable those of ordinary skill in the art to practice these and other examples. Other examples can be utilized, and structural, logical, mechanical, and electrical changes can be made to these examples. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various examples are not necessarily mutually exclusive, as some examples can be combined with one or more other examples to form new examples. The following detailed description is, therefore, not to be taken in a limiting sense.

Memory devices are typically provided as internal, semiconductor, integrated circuits in computers or other electronic devices. There are many different types of memory, including volatile and non-volatile memory.

Volatile memory requires power to maintain its data, and includes random-access memory (RAM), dynamic random-access memory (DRAM), or synchronous dynamic random-access memory (SDRAM), among others.

Non-volatile memory can retain stored data when not powered, and includes flash memory, read-only memory (ROM), electrically erasable programmable ROM (EEPROM), static RAM (SRAM), erasable programmable ROM (EPROM), resistance variable memory, such as phase-change random-access memory (PCRAM), resistive random-access memory (RRAM), magnetoresistive random-access memory (MRAM), or 3D XPoint™ memory, among others.

Flash memory is utilized as non-volatile memory for a wide range of electronic applications. Flash memory devices typically include one or more groups of one-transistor, floating gate or charge trap memory cells that allow for high memory densities, high reliability, and low power consumption.

Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a bit line.

Both NOR and NAND architecture semiconductor memory arrays are accessed through decoders that activate specific memory cells by selecting the word line coupled to their gates. In a NOR architecture semiconductor memory array, once activated, the selected memory cells place their data values on bit lines, causing different currents to flow depending on the state at which a particular cell is programmed. In a NAND architecture semiconductor memory array, a high bias voltage is applied to a drain-side select gate (SGD) line. Word lines coupled to the gates of the unselected memory cells of each group are driven at a specified pass voltage (e.g., Vpass) to operate the unselected memory cells of each group as pass transistors (e.g., to pass current in a manner unrestricted by their stored data values). Current then flows from the source line to the bit line through each series coupled group, restricted only by the selected memory cells of each group, placing current encoded data values of selected memory cells on the bit lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data.

However, flash memory cells can also represent one of more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC can refer to a memory cell that can store two bits of data per cell (e.g., one of four programmed states), a triple-level cell (TLC) can refer to a memory cell that can store three bits of data per cell (e.g., one of eight programmed states), and a quad-level cell (QLC) can store four bits of data per cell. MLC is used herein in its broader context, to can refer to any memory cell that can store more than one bit of data per cell (i.e., that can represent more than two programmed states).

Traditional memory arrays are two-dimensional (2D) structures arranged on a surface of a semiconductor substrate. To increase memory capacity for a given area, and to decrease cost, the size of the individual memory cells has decreased. However, there is a technological limit to the reduction in size of the individual memory cells, and thus, to the memory density of 2D memory arrays. In response, three-dimensional (3D) memory structures, such as 3D NAND architecture semiconductor memory devices, are being developed to further increase memory density and lower memory cost.

Such 3D NAND devices often include strings of storage cells, coupled in series (e.g., drain to source), between one or more source-side select gates (SGSs) proximate a source, and one or more drain-side select gates (SGDs) proximate a bit line. In an example, the SGSs or the SGDs can include one or more field-effect transistors (FETs) or metal-oxide semiconductor (MOS) structure devices, etc. In some examples, the strings will extend vertically, through multiple vertically spaced tiers containing respective word lines. A semiconductor structure (e.g., a polysilicon structure) may extend adjacent a string of storage cells to form a channel for the storage cells of the string. In the example of a vertical string, the polysilicon structure may be in the form of a vertically extending pillar. In some examples the string may be “folded,” and thus arranged relative to a U-shaped pillar. In other examples, multiple vertical structures may be stacked upon one another to form stacked arrays of storage cell strings.

Memory arrays or devices can be combined together to form a storage volume of a memory system, such as a solid-state drive (SSD), a Universal Flash Storage (UFS™) device, a MultiMediaCard (MMC) solid-state storage device, an embedded MMC device (eMMC™), etc. An SSD can be used as, among other things, the main storage device of a computer, having advantages over traditional hard drives with moving parts with respect to, for example, performance, size, weight, ruggedness, operating temperature range, and power consumption. For example, SSDs can have reduced seek time, latency, or other delay associated with magnetic disk drives (e.g., electromechanical, etc.). SSDs use non-volatile memory cells, such as flash memory cells to obviate internal battery supply requirements, thus allowing the drive to be more versatile and compact.

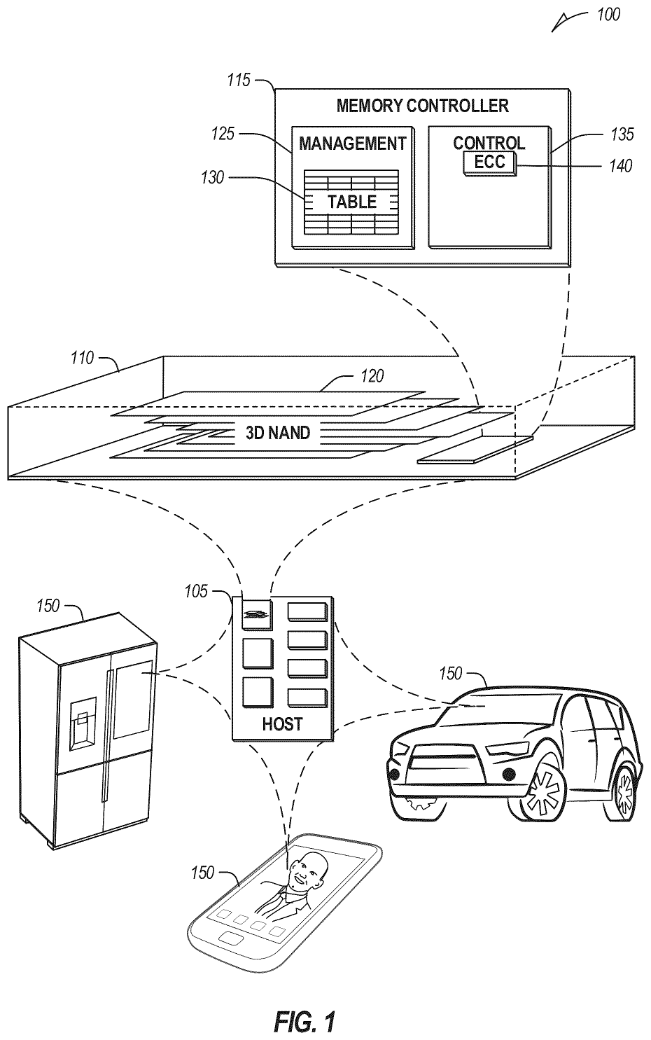

FIG. 1 illustrates an example of an environment 100 including a host device 105 and a memory device 110 configured to communicate over a communication interface. The host device 105 or the memory device 110 may be included in a variety of products 150, such as Internet of Things (IoT) devices (e.g., a refrigerator or other appliance, sensor, motor or actuator, mobile communication device, automobile, drone, etc.) to support processing, communications, or control of the product 150.

The memory device 110 includes a memory controller 115 and a memory array 120 including, for example, a number of individual memory die (e.g., three-dimensional (3D) NAND die). In 3D architecture semiconductor memory technology, vertical structures are stacked, increasing the number of tiers, physical pages, and accordingly, the density of a memory device (e.g., a storage device). In an example, the memory device 110 can be a discrete memory or storage device component of the host device 105. In other examples, the memory device 110 can be a portion of an integrated circuit (e.g., system on a chip (SOC), etc.), stacked or otherwise included with one or more other components of the host device 105.

One or more communication interfaces can be used to transfer data between the memory device 110 and one or more other components of the host device 105, such as a Serial Advanced Technology Attachment (SATA) interface, a Peripheral Component Interconnect Express (PCIe) interface, a Universal Serial Bus (USB) interface, a Universal Flash Storage (UFS) interface, an eMMC™ interface, or one or more other connectors or interfaces. The host device 105 can include a host system, an electronic device, a processor, a memory card reader, or one or more other electronic devices external to the memory device 110. In some examples, the host 105 may be a machine having some portion, or all, of the components discussed in reference to the machine 1700 of FIG. 17.

The memory controller 115 can receive instructions from the host 105, and can communicate with the memory array, such as to transfer data to (e.g., write or erase) or from (e.g., read) one or more of the memory cells, planes, sub-blocks, blocks, or pages of the memory array. The memory controller 115 can include, among other things, circuitry or firmware, including one or more components or integrated circuits. For example, the memory controller 115 can include one or more memory control units, circuits, or components configured to control access across the memory array 120 and to provide a translation layer between the host 105 and the memory device 110. The memory controller 115 can include one or more input/output (I/O) circuits, lines, or interfaces to transfer data to or from the memory array 120. The memory controller 115 can include a memory manager 125 and an array controller 135.

The memory manager 125 can include, among other things, circuitry or firmware, such as a number of components or integrated circuits associated with various memory management functions. For purposes of the present description example memory operation and management functions will be described in the context of NAND memory. Persons skilled in the art will recognize that other forms of non-volatile memory may have analogous memory operations or management functions. Such NAND management functions include wear leveling (e.g., garbage collection or reclamation), error detection or correction, block retirement, or one or more other memory management functions. The memory manager 125 can parse or format host commands (e.g., commands received from a host) into device commands (e.g., commands associated with operation of a memory array, etc.), or generate device commands (e.g., to accomplish various memory management functions) for the array controller 135 or one or more other components of the memory device 110.

The memory manager 125 can include a set of management tables 130 configured to maintain various information associated with one or more component of the memory device 110 (e.g., various information associated with a memory array, or one or more memory cells coupled to the memory controller 115). For example, the management tables 130 can include information regarding block age, block erase count, error history, or one or more error counts (e.g., a write operation error count, a read bit error count, a read operation error count, an erase error count, etc.) for one or more blocks of memory cells coupled to the memory controller 115. In certain examples, if the number of detected errors for one or more of the error counts is above a threshold, the bit error can be referred to as an uncorrectable bit error. The management tables 130 can maintain a count of correctable or uncorrectable bit errors, among other things.

The array controller 135 can include, among other things, circuitry or components configured to control memory operations associated with writing data to, reading data from, or erasing one or more memory cells of the memory device 110 coupled to the memory controller 115. The memory operations can be based on, for example, host commands received from the host 105, or internally generated by the memory manager 125 (e.g., in association with wear leveling, error detection or correction, etc.).

The array controller 135 can include an error correction code (ECC) component 140, which can include, among other things, an ECC engine or other circuitry configured to detect or correct errors associated with writing data to or reading data from one or more memory cells of the memory device 110 coupled to the memory controller 115. The memory controller 115 can be configured to actively detect and recover from error occurrences (e.g., bit errors, operation errors, etc.) associated with various operations or storage of data, while maintaining integrity of the data transferred between the host 105 and the memory device 110, or maintaining integrity of stored data (e.g., using redundant RAID storage, etc.), and can remove (e.g., retire) failing memory resources (e.g., memory cells, memory arrays, pages, blocks, etc.) to prevent future errors.

In some examples, the memory array may comprise a number of NAND dies and one or more functions of the memory controller 115 for a particular NAND die may be implemented on an on-die controller on that particular die. Other organizations and delineations of control functionality may also be utilized, such as a controller for each die, plane, superblock, block, page, and the like.

The memory array 120 can include several memory cells arranged in, for example, a number of devices, semi-conductor dies, planes, sub-blocks, blocks, or pages. In operation, data is typically written to or read from the NAND memory device 110 in pages, and erased in blocks. However, one or more memory operations (e.g., read, write, erase, etc.) can be performed on larger or smaller groups of memory cells, as desired. The data transfer size of a NAND memory device 110 is typically referred to as a page, whereas the data transfer size of a host is typically referred to as a sector.

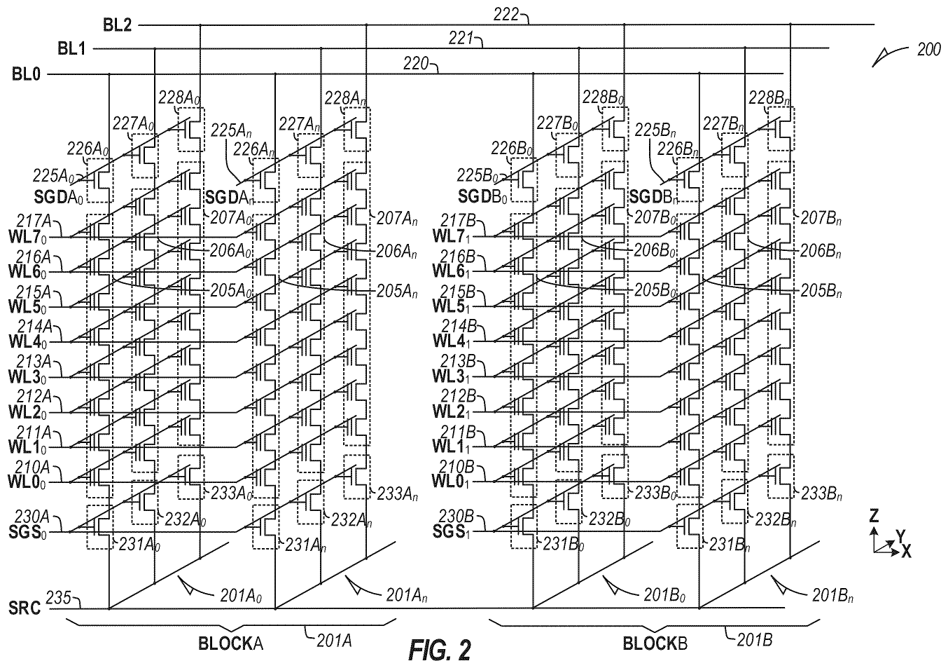

FIG. 2 illustrates an example schematic diagram of a 3D NAND architecture semiconductor memory array 200 including a number of strings of memory cells (e.g., first-third A₀ memory strings 205A₀-207A₀, first-third Aₙ memory strings 205Aₙ-207Aₙ, first-third B₀ memory strings 205B₀-207B₀, first-third Bₙ memory strings 205Bₙ-207Bₙ, etc.), organized in blocks (e.g., block A 201A, block B 201B, etc.) and sub-blocks (e.g., sub-block A₀ 201A₀, sub-block Aₙ 201Aₙ, sub-block B₀ 201B₀, sub-block Bₙ 201Bₙ, etc.). The memory array 200 represents a portion of a greater number of similar structures that would typically be found in a block, device, or other unit of a memory device.

Each string of memory cells includes a number of tiers of charge storage transistors (e.g., floating gate transistors, charge-trapping structures, etc.) stacked in the Z direction, source to drain, between a source line (SRC) 235 or a source-side select gate (SGS) (e.g., first-third A₀ SGS 231A₀-233A₀, first-third Aₙ SGS 231Aₙ-233Aₙ, first-third B₀ SGS 231B₀-233B₀, first-third Bₙ SGS 231Bₙ-233Bₙ, etc.) and a drain-side select gate (SGD) (e.g., first-third A₀ SGD 226A₀-228A₀, first-third Aₙ SGD 226Aₙ-228Aₙ, first-third B₀ SGD 226B₀-228B₀, first-third Bₙ SGD 226Bₙ-228Bₙ, etc.). Each string of memory cells in the 3D memory array can be arranged along the X direction as data lines (e.g., bit lines (BL) BL0-BL2 220-222), and along the Y direction as physical pages.

Within a physical page, each tier represents a row of memory cells, and each string of memory cells represents a column. A sub-block can include one or more physical pages. A block can include a number of sub-blocks (or physical pages) (e.g., 128, 256, 384, etc.). Although illustrated herein as having two blocks, each block having two sub-blocks, each sub-block having a single physical page, each physical page having three strings of memory cells, and each string having 8 tiers of memory cells, in other examples, the memory array 200 can include more or fewer blocks, sub-blocks, physical pages, strings of memory cells, memory cells, or tiers. For example, each string of memory cells can include more or fewer tiers (e.g., 16, 32, 64, 128, etc.), as well as one or more additional tiers of semiconductor material above or below the charge storage transistors (e.g., select gates, data lines, etc.), as desired. As an example, a 48 GB TLC NAND memory device can include 18,592 bytes (B) of data per page (16,384+2208 bytes), 1536 pages per block, 548 blocks per plane, and 4 or more planes per device.

Each memory cell in the memory array 200 includes a control gate (CG) coupled to (e.g., electrically or otherwise operatively connected to) an access line (e.g., word lines (WL) WL0₀-WL7₀ 210A-217A, WL0₁-WL7₁ 210B-217B, etc.), which collectively couples the control gates (CGs) across a specific tier, or a portion of a tier, as desired. Specific tiers in the 3D memory array, and accordingly, specific memory cells in a string, can be accessed or controlled using respective access lines. Groups of select gates can be accessed using various select lines. For example, first-third A₀ SGD 226A₀-228A₀ can be accessed using an A₀ SGD line SGDA₀ 225A₀, first-third Aₙ SGD 226Aₙ-228Aₙ can be accessed using an SGD line SGDAₙ 225Aₙ, first-third B₀ SGD 226B₀-228B₀ can be accessed using an B₀ SGD line SGDB₀ 225B₀, and first-third Bₙ SGD 226Bₙ-228Bₙ can be accessed using an Bₙ SGD line SGDBₙ 225Bₙ. First-third A₀ SGS 231A₀-233A₀ and first-third Aₙ SGS 231Aₙ-233Aₙ can be accessed using a gate select line SGS₀ 230A, and first-third B₀ SGS 231B₀-233B₀ and first-third Bₙ SGS 231Bₙ-233Bₙ can be accessed using a gate select line SGS₁ 230B.

In an example, the memory array 200 can include a number of tiers of semiconductor material (e.g., polysilicon, etc.) configured to couple the control gates (CGs) of each memory cell or select gate (or a portion of the CGs or select gates) of a respective tier of the array. Specific strings of memory cells in the array can be accessed, selected, or controlled using a combination of bit lines (BLs) and select gates, etc., and specific memory cells at one or more tiers in the specific strings can be accessed, selected, or controlled using one or more access lines (e.g., word lines).

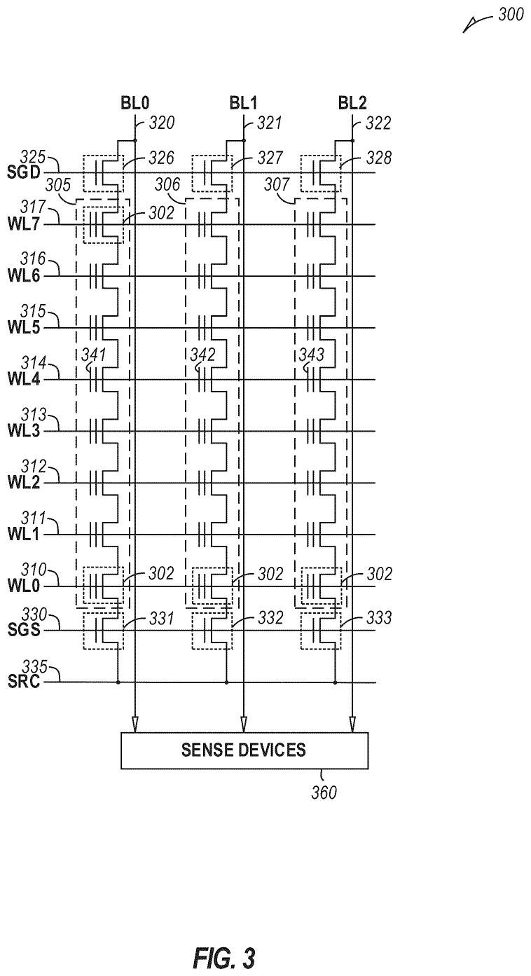

FIG. 3 illustrates an example schematic diagram of a portion of a NAND architecture semiconductor memory array 300 including a plurality of memory cells 302 arranged in a two-dimensional array of strings (e.g., first-third strings 305-307) and tiers (e.g., illustrated as respective word lines (WL) WL0-WL7 310-317, a drain-side select gate (SGD) line 325, a source-side select gate (SGS) line 330, etc.), and sense amplifiers or devices 360. For example, the memory array 300 can illustrate an example schematic diagram of a portion of one physical page of memory cells of a 3D NAND architecture semiconductor memory device, such as illustrated in FIG. 2.

Each string of memory cells is coupled to a source line (SRC) using a respective source-side select gate (SGS) (e.g., first-third SGS 331-333), and to a respective data line (e.g., first-third bit lines (BL) BL0-BL2 320-322) using a respective drain-side select gate (SGD) (e.g., first-third SGD 326-328). Although illustrated with 8 tiers (e.g., using word lines (WL) WL0-WL7 310-317) and three data lines (BL0-BL2 326-328) in the example of FIG. 3, other examples can include strings of memory cells having more or fewer tiers or data lines, as desired.

In a NAND architecture semiconductor memory array, such as the example memory array 300, the state of a selected memory cell 302 can be accessed by sensing a current or voltage variation associated with a particular data line containing the selected memory cell. The memory array 300 can be accessed (e.g., by a control circuit, one or more processors, digital logic, etc.) using one or more drivers. In an example, one or more drivers can activate a specific memory cell, or set of memory cells, by driving a particular potential to one or more data lines (e.g., bit lines BL0-BL2), access lines (e.g., word lines WL0-WL7), or select gates, depending on the type of operation desired to be performed on the specific memory cell or set of memory cells.

To program or write data to a memory cell, a programming voltage (Vpgm) (e.g., one or more programming pulses, etc.) can be applied to selected word lines (e.g., WL4), and thus, to a control gate of each memory cell coupled to the selected word lines (e.g., first-third control gates (CGs) 341-343 of the memory cells coupled to WL4). Programming pulses can begin, for example, at or near 15V, and, in certain examples, can increase in magnitude during each programming pulse application. While the program voltage is applied to the selected word lines, a potential, such as a ground potential (e.g., Vss), can be applied to the data lines (e.g., bit lines) and substrates (and thus the channels, between the sources and drains) of the memory cells targeted for programming, resulting in a charge transfer (e.g., direct injection or Fowler-Nordheim (FN) tunneling, etc.) from the channels to the floating gates of the targeted memory cells.

In contrast, a pass voltage (Vpass) can be applied to one or more word lines having memory cells that are not targeted for programming, or an inhibit voltage (e.g., Vcc) can be applied to data lines (e.g., bit lines) having memory cells that are not targeted for programming, for example, to inhibit charge from being transferred from the channels to the floating gates of such non-targeted memory cells. The pass voltage can be variable, depending, for example, on the proximity of the applied pass voltages to a word line targeted for programming. The inhibit voltage can include a supply voltage (Vcc), such as a voltage from an external source or supply (e.g., a battery, an AC-to-DC converter, etc.), relative to a ground potential (e.g., Vss).

As an example, if a programming voltage (e.g., 15V or more) is applied to a specific word line, such as WL4, a pass voltage of 10V can be applied to one or more other word lines, such as WL3, WL5, etc., to inhibit programming of non-targeted memory cells, or to retain the values stored on such memory cells not targeted for programming. As the distance between an applied program voltage and the non-targeted memory cells increases, the pass voltage required to refrain from programming the non-targeted memory cells can decrease. For example, where a programming voltage of 15V is applied to WL4, a pass voltage of 10V can be applied to WL3 and WL5, a pass voltage of 8V can be applied to WL2 and WL6, a pass voltage of 7V can be applied to WL1 and WL7, etc. In other examples, the pass voltages, or number of word lines, etc., can be higher or lower, or more or less.

The sense amplifiers 360, coupled to one or more of the data lines (e.g., first, second, or third bit lines (BL0-BL2) 320-322), can detect the state of each memory cell in respective data lines by sensing a voltage or current on a particular data line.

Between applications of one or more programming pulses (e.g., Vpgm), a verify operation can be performed to determine if a selected memory cell has reached its intended programmed state. If the selected memory cell has reached its intended programmed state, it can be inhibited from further programming. If the selected memory cell has not reached its intended programmed state, additional programming pulses can be applied. If the selected memory cell has not reached its intended programmed state after a particular number of programming pulses (e.g., a maximum number), the selected memory cell, or a string, block, or page associated with such selected memory cell, can be marked as defective.

To erase a memory cell or a group of memory cells (e.g., erasure is typically performed in blocks or sub-blocks), an erasure voltage (Vers) (e.g., typically Vpgm) can be applied to the substrates (and thus the channels, between the sources and drains) of the memory cells targeted for erasure (e.g., using one or more bit lines, select gates, etc.), while the word lines of the targeted memory cells are kept at a potential, such as a ground potential (e.g., Vss), resulting in a charge transfer (e.g., direct injection or Fowler-Nordheim (FN) tunneling, etc.) from the floating gates of the targeted memory cells to the channels.

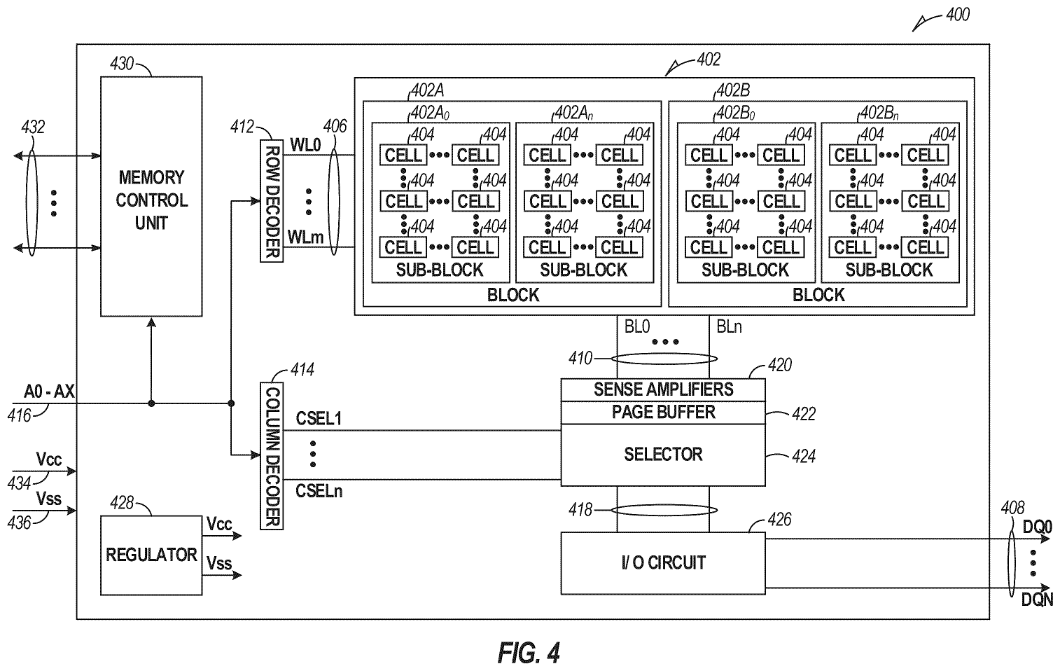

FIG. 4 illustrates an example block diagram of a memory device 400 including a memory array 402 having a plurality of memory cells 404, and one or more circuits or components to provide communication with, or perform one or more memory operations on, the memory array 402. The memory device 400 can include a row decoder 412, a column decoder 414, sense amplifiers 420, a page buffer 422, a selector 424, an input/output (I/O) circuit 426, and a memory control unit 430.

The memory cells 404 of the memory array 402 can be arranged in blocks, such as first and second blocks 402A, 402B. Each block can include sub-blocks. For example, the first block 402A can include first and second sub-blocks 402A₀, 402Aₙ, and the second block 402B can include first and second sub-blocks 402B₀, 402Bₙ. Each sub-block can include a number of physical pages, each page including a number of memory cells 404. Although illustrated herein as having two blocks, each block having two sub-blocks, and each sub-block having a number of memory cells 404, in other examples, the memory array 402 can include more or fewer blocks, sub-blocks, memory cells, etc. In other examples, the memory cells 404 can be arranged in a number of rows, columns, pages, sub-blocks, blocks, etc., and accessed using, for example, access lines 406, first data lines 410, or one or more select gates, source lines, etc.

The memory control unit 430 can control memory operations of the memory device 400 according to one or more signals or instructions received on control lines 432, including, for example, one or more clock signals or control signals that indicate a desired operation (e.g., write, read, erase, etc.), or address signals (A0-AX) received on one or more address lines 416. One or more devices external to the memory device 400 can control the values of the control signals on the control lines 432, or the address signals on the address line 416. Examples of devices external to the memory device 400 can include, but are not limited to, a host, a memory controller, a processor, or one or more circuits or components not illustrated in FIG. 4.

The memory device 400 can use access lines 406 and first data lines 410 to transfer data to (e.g., write or erase) or from (e.g., read) one or more of the memory cells 404. The row decoder 412 and the column decoder 414 can receive and decode the address signals (A0-AX) from the address line 416, can determine which of the memory cells 404 are to be accessed, and can provide signals to one or more of the access lines 406 (e.g., one or more of a plurality of word lines (WL0-WLm)) or the first data lines 410 (e.g., one or more of a plurality of bit lines (BL0-BLn)), such as described above.

The memory device 400 can include sense circuitry, such as the sense amplifiers 420, configured to determine the values of data on (e.g., read), or to determine the values of data to be written to, the memory cells 404 using the first data lines 410. For example, in a selected string of memory cells 404, one or more of the sense amplifiers 420 can read a logic level in the selected memory cell 404 in response to a read current flowing in the memory array 402 through the selected string to the data lines 410.

One or more devices external to the memory device 400 can communicate with the memory device 400 using the I/O lines (DQ0-DQN) 408, address lines 416 (A0-AX), or control lines 432. The input/output (I/O) circuit 426 can transfer values of data in or out of the memory device 400, such as in or out of the page buffer 422 or the memory array 402, using the I/O lines 408, according to, for example, the control lines 432 and address lines 416. The page buffer 422 can store data received from the one or more devices external to the memory device 400 before the data is programmed into relevant portions of the memory array 402, or can store data read from the memory array 402 before the data is transmitted to the one or more devices external to the memory device 400.

The column decoder 414 can receive and decode address signals (A0-AX) into one or more column select signals (CSEL1-CSELn). The selector 424 (e.g., a select circuit) can receive the column select signals (CSEL1-CSELn) and select data in the page buffer 422 representing values of data to be read from or to be programmed into memory cells 404. Selected data can be transferred between the page buffer 422 and the I/O circuit 426 using second data lines 418.

The memory control unit 430 can receive positive and negative supply signals, such as a supply voltage (Vcc) 434 and a negative supply (Vss) 436 (e.g., a ground potential), from an external source or supply (e.g., an internal or external battery, an AC-to-DC converter, etc.). In certain examples, the memory control unit 430 can include a regulator 428 to internally provide positive or negative supply signals.

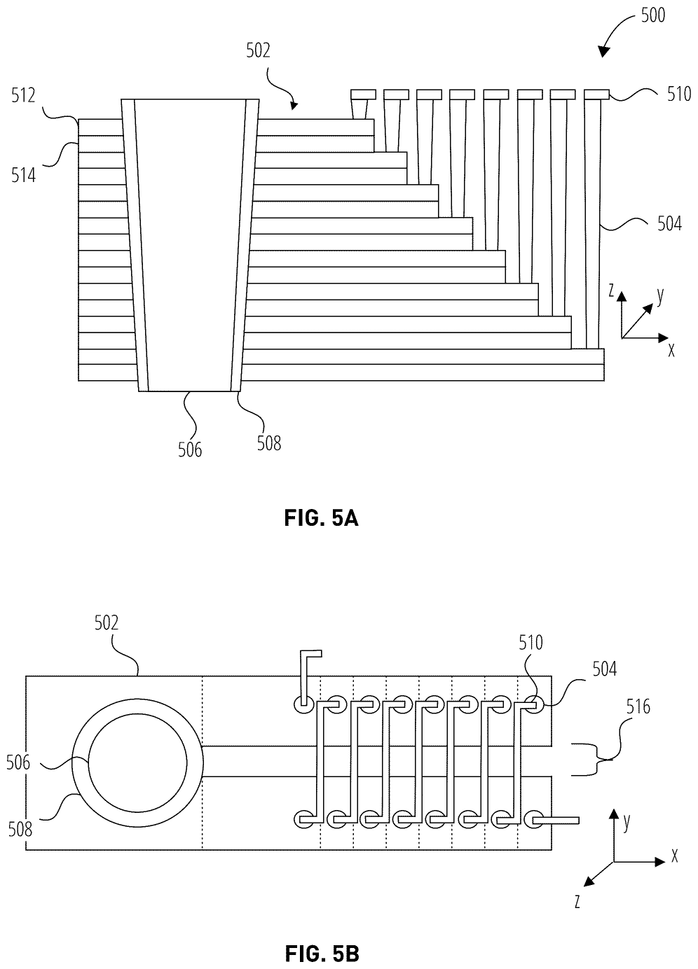

FIG. 5A illustrates an example inductor 500 in a cross-sectional view, according to some examples. The inductor 500 is formed using one or more structures formed during or in coordination with 3D NAND structure fabrication, such as a staircase 502 structure and a set of pillars 504, according to some examples. The inductor 500 is formed by making one or more modifications to the one or more existing 3D NAND structures, such as forming a magnetic core 506, an oxide layer 508, and/or a set of contact straps 510.

The staircase 502 is a structure with tiers that are stepped, resembling a staircase. The staircase 502 has a plurality of tiers that form the “steps” of the staircase. That is, each tier comprises a step of the staircase 502. Each tier includes at least a conductive layer 512. According to some examples, each tier includes an insulative layer 514 as well. The relative height (z-direction) of the conductive layer 512 to the insulative layer 514 may vary in different examples. Each tier contains a word line in the conductive layer 512, according to some examples where the staircase 502 is formed of existing NAND structures. The conductive layer 512 may be formed of any electrically conductive material, such as a metal. The insulative layer 514 may be formed of any electrically insulative material, such as an oxide. According to some embodiments, the conductive layer 512 is formed of tungsten and the insulative layer 514 is formed of a silicon-oxide.

Each tier in the staircase 502 has a shorter length (x-direction) than the adjacent tier below it. According to some examples, the steps in the tiers of the staircase 502 are equally spaced in the x-direction.

The figures herein, including FIG. 5A, are provided for illustration and are not necessarily to scale. In some embodiments, the staircase 502 contains many additional tiers. According to some examples, the staircase 502 has 232 tiers. Further, the x-direction is not necessarily to scale. The staircase 502 in FIG. 5A shows an exemplary singular staircase structure for NAND, and the exemplary singular staircase structure is extendable for any staircase type such as a folded staircase or double-sided staircase or similar. For example, in some examples, the stepped portion of the staircase 502 is approximately 10% of the overall length of the staircase 502 in the x-direction.

According to some examples, the staircase 502 is formed during fabrication of a 3D NAND memory device. For example, during 3D NAND fabrication, a cuboid structure is formed by depositing alternating layers of an oxide and a nitride in a process known as stack deposition. In some examples, the oxide is a silicon-oxide, and the nitride is a silicon-nitride. Depending on the composition of the oxide and the nitride, the alternating layers are deposited on a substrate by chemical vapor deposition (CVD) and/or physical vapor deposition (PVD), according to some examples. According to some examples, the alternating layers are deposited one layer at a time to form the layered cuboid structure. According to some examples, two or more layered cuboid structures are formed and stacked on top of one another in a process known as string stacking.

The layered cuboid structure is etched to form the staircase 502. The etching includes at least etching to form a “step” in each tier. In NAND applications, the stepped portion of the staircase 502 enables access to each word line. According to some examples, a combination of masks and/or lithography are used to form the staircase 502. For example, a thick layer of a photoresist material is deposited on top of the layered cuboid structure, which forms a mask for etching. The photoresist is selectively etched to create a hole in the mask area of a single step. The layered cuboid structure with the photoresist is etched (e.g., using a plasma etch process) through a single oxide layer to expose a nitride layer and form a step-like shape. The photoresist is selectively etched laterally or sideways to remove another area of a single step, increasing the size of the hole to that of two steps. This process is known as pull-back etching. The layered cuboid structure is etched again, through an entire tier to the next nitride layer, forming another step-like shape. The pull-back etch process is repeated as needed to etch all steps in the staircase 502.

The stepped layered structure is backfilled with a metal, according to some examples. For example, the nitride layers are etched away, and the vacancies are backfilled with a conductive material to form the conductive layers 512. The remaining oxide forms the insulative layers 514. According to some examples, a thin layer of titanium nitride is deposited (e.g., using PVD) prior to backfilling. The process of etching the nitride and backfilling with a conductive material is known as lateral word line backfill, according to some 3D NAND fabrication processes.

According to some examples, the inductor 500, including the staircase 502, is formed independently of 3D NAND fabrication processes. For example, the staircase 502 may include any number of tiers (e.g., 5 tiers) and is not limited to the number of layers used in 3D NAND applications. For example, the staircase 502 is formed additively by layering tiers of successively decreasing length (e.g., in the x-direction). Additionally, or alternatively, 3D NAND fabrication processes may be used independently of forming 3D NAND structures elsewhere on-chip. That is, the inductor 500 can be formed on a chip without any 3D NAND structures.

The set of pillars 504 are a set of electrically conductive column-like structures. Each pillar 504 is in contact with a conductive layer 512 of a respective tier of the staircase 502. For example, a pillar 504 makes contact with a conductive layer 512 on the “stepped” portion of the staircase 502. That is, a pillar 504 contacts on the upward-facing (+2-direction) surface of the stepped portion of a conductive layer 512 of a tier, referred to herein as a contact surface. That is, the contact surface provides an area to electrically couple each pillar 504 to a respective tier of the staircase 502. The set of pillars 504 are formed of a conductive material, such as a metal. According to some embodiments, the set of pillars 504 are formed of tungsten.

The set of pillars 504 are formed during some processes of fabricating a 3D NAND memory device. According to some examples, the set of pillars 504 are formed to attach to each tier in the staircase 502 to enable access to each word line as part of the 3D NAND fabrication. That is, the pillars 504 enable contact with the word lines in 3D NAND applications. For example, to form the set of pillars 504, some processes of fabricating 3D NAND include steps such as filling an oxide (or other insulator) over the staircase 502, applying a mask and etching contact holes into the oxide. The contact holes are filled with a conductive material (e.g., tungsten) to form the set of pillars 504.

The magnetic core 506 is a core of ferroelectric material, according to some examples. The magnetic core 506 is optional and may be excluded in some examples. The magnetic core 506 improves the inductance of the inductor 500. That is, the magnetic core 506 amplifies the magnetic field produced by the inductor 500 when in use. A magnetic core 506 can increase the inductance by a factor of thousands in some instances. According to some examples, a cobalt titanium zirconium alloy (CoTaZr alloy) forms the magnetic core 506. CoTaZr alloys can improve the permeability of the inductor. For example, the Co₉₀Ta₅Zr₅ alloy has a permeability of ˜600 Henries/meter; a significant increase as compared to the permeability of free space of 4×10⁻⁷ Henries/meter.

Usage of magnetic core is optional. Some applications needing lower inductance density may do without a magnetic core.

The oxide layer 508 is a layer of insulation surrounding the magnetic core 506, according to some examples. The oxide layer 508 insulates the magnetic core 506 from the conductive layers 512, and vice versa. According to some examples, the oxide layer 508 is formed of silicon oxide, a nitride, or other dielectric materials. According to some examples, chemical vapor deposition (CVD), or atomic layer deposition (ALD) is used to form the oxide layer 508 formed of oxide or nitride.

The magnetic core 506 and oxide layer 508 can be formed separately from 3D NAND structure fabrication. For example, the magnetic core 506 and oxide layer 508 are formed by applying a mask and etching a column-shaped hole into the staircase 502, according to some examples. The oxide layer 508 is deposited as a layer on the walls of the column-shaped hole. For example, the oxide layer 508 is deposited using physical vapor deposition (PVD), CVD, ALD, or another deposition method. The ferroelectric material is deposited to fill the column-shaped hole, forming the magnetic core 506. According to some examples, the column-shaped hole may be formed using processes relating to channel etching in 3D NAND fabrication processes.

The set of contact straps 510 are a set of electrically conductive structures. Each contact strap 510 connects one tier of the staircase 502 to a neighboring tier of the staircase 502 through the pillars 504. That is, each contact strap 510 connects one pillar 504 to another pillar 504. Further, each contact strap 510 connects a first pillar 504 that is connected to a first tier of the staircase 502 to a second pillar 504 that is connected to a second tier of the staircase 502, where the first tier is a different tier of the staircase 502 than the second tier.

The contact straps 510 may take on different shapes in different examples. In the illustrative example inductor 500, each contact strap 510 is a Z-shape, as shown in FIG. 5B. Other contact strap 510 shapes are possible, for example, L-shaped, S-shaped, rod-shaped, zig-zag-shaped, linear, or other amorphous shaped contact straps 510. Further, the individual contact straps 510 may differ in shape from one another. That is, the contact straps 510 may take on any shape necessary to connect one pillar 504 to the next, as applicable.

The contact straps 510 are formed of metal, such as tungsten, or another conductive material. According to some examples, the contact straps 510 are formed through a process similar to that of forming the bit lines in 3D NAND. For example, a hard mask is applied and selectively etched to form holes in the shapes of the desired contacts (e.g., Z-shaped, as shown in FIG. 5B). Then a metal (or other conductive material) is deposited to fill the holes in the mask. The mask is etched away, leaving the set of contact straps 510. This process is highly scalable since the set of contact straps 510 are all formed simultaneously. That is, the time consumed by contact strap 510 formation is independent of the number of contact straps 510 in the set of contact straps 510. The contact straps 510 may be formed by alternative methods, such as a laser metal deposition.

FIG. 5B illustrates the example inductor 500 in a top-down view, according to some examples. The top-down view enables visualization of the set of contact straps 510 and a slit 516 of the inductor 500. The top-down view also depicts the staircase 502, the set of pillars 504, the magnetic core 506, the oxide layer 508, and the set of contact straps 510.

The slit 516 bifurcates the staircase 502 lengthwise (along the x-axis) perpendicular to the steps formed in the tiers, as depicted in FIG. 5B. The slit 516 separates one side of the tiers of the staircase 502 from a second side of the tiers. According to some examples, the slit 516 is filled. In some examples, the slit is filled with an insulative material, such as with the oxide layer 508. According to some examples, the slit 516 is empty (e.g., not filled with a material).

According to some examples, the slit 516 is formed during or in coordination with fabrication of 3D NAND structures, according to some examples. According to some examples, fabrication of the slit 516 is performed after the pull-back etch to form the steps in the tiers of the staircase 502 and before the lateral word line backfill. For example, a hard mask is deposited on the stepped layered structure discussed previously. The hard mask is selectively etched to form the shape of the slit in the hard mask. The entire structure is etched to form the slit 516 in the stepped layered structure, which becomes the staircase 502. According to some examples, the slit 516 is etched before the pull-back etch to form the steps in the tiers of the staircase 502.

FIG. 5B illustrates an example of Z-shaped contact straps 510. Each Z-shaped contact strap 510 connects, for example, a first pillar 504 on a first tier on a first side of the slit 516 to a second pillar on a second tier on a second side of the slit 516. As depicted, each contact strap 510 connects each tier to its immediate neighboring tier. According to some examples, each contact strap 510 spans the width of the slit 516 in a direction transverse to the length of the slit 516.

According to some examples, the contact straps 510 connect non-consecutive tiers. The set of pillars 504 each terminating at a uniform height facilitates connection to non-consecutive tiers. For example, a contact strap 510 connects a first pillar of a first tier to a second pillar of a tier that is five tiers away. In another example, the second pillar is of a tier that is 232 tiers away. The structure of the inductor 500 is highly flexible and can be adapted to fit various design constraints.

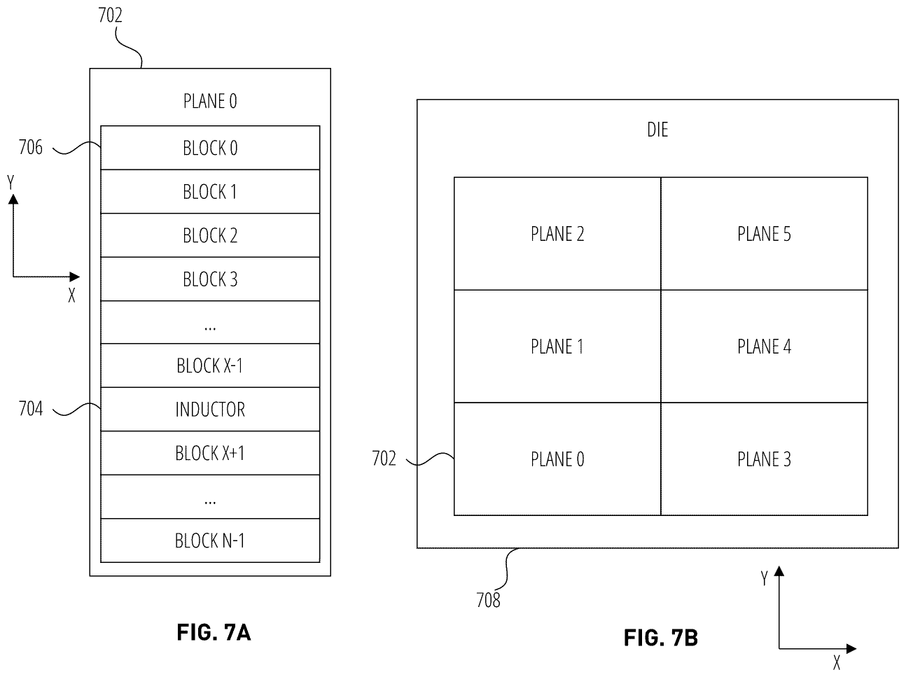

Through the set of pillars 504 and the set of contact straps 510, multiple tiers in the staircase 502 can be connected. In some examples, all of the tiers are used, and in other examples, fewer than all of the tiers are used. The resultant structure of the inductor 500 resembles a solenoid. Solenoid structures are known to provide efficient inductance due to their shape, as discussed in relation to FIG. 7A.

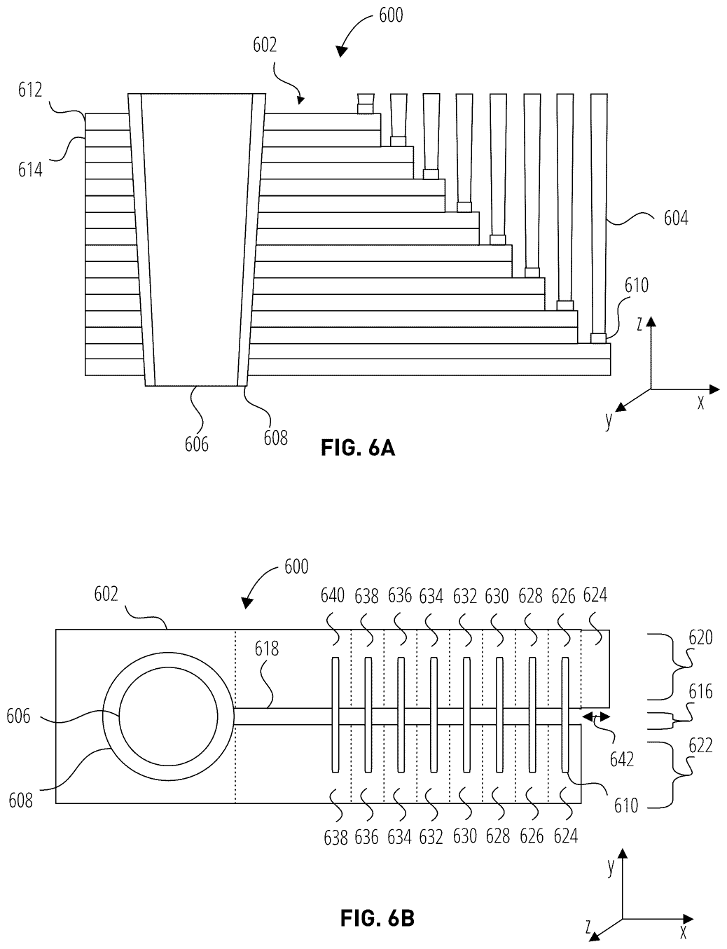

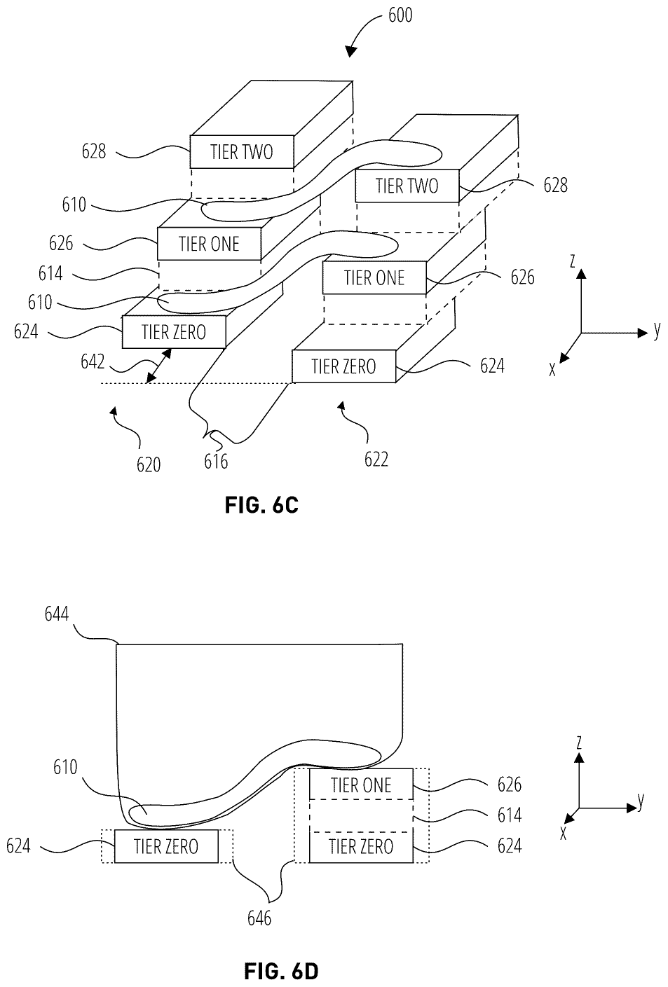

FIG. 6A illustrates an example inductor 600 in a cross-sectional view, according to some examples. The inductor 600 is formed using one or more structures formed during or in coordination with 3D NAND structure fabrication, such as a staircase 602 structure and a set of pillars 604, according to some examples. The inductor 600 is formed by making one or more modifications to the one or more existing 3D NAND structures, such as forming a magnetic core 606, an oxide layer 608, and/or a set of contact straps 510.

The staircase 602, which can comprise an example of the staircase 502, can include a plurality of tiers, each tier including a conductive layer 612 and an insulative layer 614. The set of pillars 604 can comprise an example of the set of pillars 504, according to some examples. The magnetic core 606 can comprise an example of the magnetic core 506. The oxide layer 608 can comprise an example of the oxide layer 508. The set of contact straps 610 can comprise an example of the set of contact straps 510.

In an example, the inductor 600 comprises local contact straps 610 to lower contact resistance as compared to the inductor 500. The local contact straps 610 are further illustrated in FIG. 6B and FIG. 6C.

FIG. 6B illustrates an example of the inductor 600 in a top-down view, according to some examples. The top-down view enables visualization of the set of contact straps 610 and a slit 616 of the inductor 600. The top-down view also depicts the staircase 602, the magnetic core 606, the oxide layer 608, and the set of contact straps 610, among other features. The slit 616 can comprise an example of the slit 516 from the inductor 500.

According to some examples, the slit 616 is filled with a slit insulative layer 618, such as an oxide. The slit 616 can be filled with the slit insulative layer 618 after the set of contact straps 610 are formed, as discussed in relation to FIG. 6C and FIG. 6D, according to some examples. According to some examples, the slit 616 is not filled with a material.

The slit 616 bifurcates the staircase 602 into a first set of steps 620 in the tiers and a second set of steps 622 in the tiers. That is, the plurality of tiers is bifurcated such that each tier has two stepped formations, one on either side of the slit. The first set of steps 620 is offset 642 from the second set of steps 622. That is, the steps directly across the slit 616 from one another can have different heights. The offset 642 is formed, for example, by an additional staircase etch process to etch the second set of steps 622 an additional step-worth of height (e.g., in the z-direction). That is, each “step” in the first set of steps 620 is one step-worth of height (e.g., in the z-direction) higher than the respective corresponding step directly across the slit 616 in the second set of steps 622.

In the example depicted in FIG. 6B, the first set of steps 620 begins at tier zero 624 and terminates at tier eight 640. The second set of steps 622 begins at tier zero 624 and terminates at tier seven 638, which can be one step lower than tier eight 640. The tier zero 624 of the first set of steps 620 is spaced by the offset 642 (in the x-direction) from the tier zero 624 of the second set of steps 622.

According to some examples, each numbered tier is continuous on the interior of the inductor 600. That is the tier zero 624 of the first set of steps 620 and the tier zero 624 of the second set of steps 622 are exposed portions of a contiguous tier zero 624 on the interior of the inductor 600.

According to some examples, the first set of steps 620 begins at tier one 626 and terminates at tier eight 640. The second set of steps 622 begins one step lower, at tier zero 624 and terminates at tier seven 638, which can be one step lower than tier eight 640. That is, in some examples, the exposed portion of tier zero 624 of the first set of steps 620 and the offset 642, are omitted. According to some examples, the exposed portion of tier zero 624 of the first set of steps 620 is not coupled to a contact strap.

For example, starting from the bottom of the staircase 602, the bottom-most step is tier zero 624 in the second set of steps 622. Tier zero 624 is connected by a contact strap 610 to tier one 626 directly across the slit 616 in the first set of steps 620. Similarly, tier one 626 on the second set of steps 622 side is connected to tier two 628 on the first set of steps 620 by another contact strap 610. Tier two 628 is connected to tier three 630; tier three 630 is connected to tier four 632; tier four 632 is connected to tier five 634; tier five 634 is connected to tier six 636; tier six 636 is connected to tier seven 638. Tier seven 638 on the second set of steps 622 is connected to tier eight 640 on the first set of steps 620 by another contact strap 610, completing a solenoid-like structure.

The number of tiers shown is for illustrative purposes. Other example inductors 600 may have additional or fewer tiers.

FIG. 6C illustrates example contact straps 610 on tiers of the example inductor 600, according to some examples. FIG. 6C also illustrates the offset 642 between the first set of steps 620 and the second set of steps 622, according to some examples. That is, according to some examples, the second set of steps 622 is offset 642 from the first set of steps 620 in the x-direction. The offset 642 is, for example, less than or equal to the width (x-direction) of one step.

According to some examples, the contact straps 610 are formed in an S-shape to span the slit 616 and the offset 642, as depicted. That is, according to some examples, each contact strap 610 spans the width of the slit 616 in a direction transverse to the length of the slit. For example, an S-shaped (or S-like-shaped) contact strap 610 connects tier zero 624 of the second set of steps 622 to tier one 626 of the first set of steps 620 across the slit 616. Another S-shaped contact strap 610 connects tier one 626 of the second set of steps 622 to tier two 628 of the first set of steps 620 across the slit 616.

FIG. 6D illustrates formation of contact straps 610 on tiers of an example inductor, according to some examples. The contact straps 610 may be formed by any of the methods discussed previously in relation to FIG. 5A.

Additionally, or alternatively, the contact straps 610 are formed through a process on record (POR) contact etch that reaches down to the conductive layer 612. This process carries a potential to short to a lower tier in the staircase 602. The short can be prevented by using a liner 644 when forming the contact straps 610. The metal that forms the contact strap 610 is deposited, connecting one tier to the offset 642 tier across the slit 616.

Additionally, or alternatively, a spacer 646 insulates the interior side walls of the first set of steps 620 and the second set of steps 622. According to some examples, the spacer 646 takes the form of a side wall or thin layer formed of an oxide, a nitride, or another insulative material. Similar to the liner 644, inclusion of the spacer 646 on the interior side walls can prevent shorts by insulating the conductive layers on the sides. The spacer 646 does not insulate the tops of each tier, leaving each respective upper surface available for electrical coupling with the contact strap 610. Additionally, the spacer can provide adhesion and lower resistance between the contact straps 610 and conductive layers of the staircase 602.

In an example, the slit 616 is filled with the slit insulative layer 618 after all the contact straps 610 are formed because the contact straps 610 span the slit 616. After the set of contact straps 610 are formed, the slit 616 is backfilled with oxide, according to some examples.

FIG. 7A illustrates an example NAND plane 702 with an on-chip inductor 704, according to some examples. The plane 702 is formed of an array of blocks 706 and an inductor 704, according to some examples. The plane may have additional of fewer blocks 706 and/or inductors 704, according to some examples. The plane 702 includes N blocks 706, numbered 0 to N−1, according to some examples. According to some examples, there are five-hundred seventy-four blocks 706 within each plane 702 (e.g., N=574).

Each block 706 is a two-dimensional matrix of NAND cells and peripheral circuitry, including a number of pages and strings. The total number of NAND cells in a block 706 can be found by multiplying the number of pages by the number of strings. Each block 706 in the plane 702 can have the same dimensions (e.g., number of pages and number of strings), according to some examples.

A string is a number of NAND cells along a bit line (BL) and, for example, form the columns of the block 706. According to some examples, a string contains 32, 64, 96, 128, or 232 NAND cells. All strings in a memory array are connected at one end to a common source line. Each string further contains two control mechanisms in series with the NAND cells: (1) a string select transistor connected via a string select line and (2) a ground select transistor connected via a ground select line.

A page is a number of NAND cells along a word line and, for example, form the rows of the block 706. According to some examples, a page contains 32 k, 64 k, or 128 k NAND cells, though the page size may be referred to in bytes (e.g., 4 k, 8 k, etc., bytes).

The inductor 704 is any inductor described herein, such as inductor 500 or inductor 600. The inductor 704 is depicted top-down in FIG. 7A. According to some examples, the inductor 704 is formed on-chip in an area that could alternatively hold a block 706, and vice versa. That is, the inductor 704 has the same dimensions as the blocks 706 in the plane 702. For example, the inductor 704 is formed between two blocks 706, block x−1 and block x+1, where x is any number less than N−1 and greater than 0. Additionally, or alternatively, the inductor 704 may be formed at an end block of the plane, e.g., in the place of block 0 or block N−1. For example, according to some examples, the inductor 500 is formed at an end block of the plane. The illustration of the location of the inductor 704 in FIG. 7A is not meant to be limiting.

The formation of the inductor 704 uses existing NAND structures, according to some examples. For example, take a 3D NAND structure with 232 tiers. That is, a string in a block 706 contains 232active WL tiers. Thus, the formed inductor 704 can have up to 232 turns. The inductance of a solenoid is proportional to the square of the number of turns in the solenoid:

$$L = \frac{{n}^{2} \cdot {μ}_{0} \cdot a}{l}$$

where L represents inductance, n represents the number of turns in the solenoid, μ₀ is the permeability of free space (i.e., 4×10⁻⁷ Henries/meter), a represents the cross-sectional area of the solenoid, and/represents the length of the solenoid. Thus, an inductor 704 with 232 turns has an inductance proportional to 2322. Accordingly, the inductor 704 has an inductance that is sufficiently high to be commercially viable and useful for on-chip functions.

Further, forming the on-chip inductor 704 with high inductance scales well. For example, as NAND scales, more tiers are added to the staircase. Thus, as the number of tiers in the staircase increases, the inductance increases as a square. Further, the process steps involved in forming the inductor 704 from the NAND structures scales relative to the process steps used to form 3D NAND.

Additionally, as 3D NAND structures continue to grow in number of tiers (e.g., corresponding to a number of turns in a solenoid structure, according to examples herein) in the staircase as well as size of blocks (e.g., corresponding to a cross-sectional area of a solenoid structure), the inductance of the on-chip inductor will further increase. The approaches presented herein provide flexibility of design alongside scalability to form high-inductance on-chip inductors.

FIG. 7B illustrates an example NAND die 708, according to some examples. Each die 708 includes a number of planes 702. The number of planes 702 and geometry of organizing the planes 702 on the die 708 may vary according to different examples. In the example depicted in FIG. 7B, the die 708 includes six planes 702, where each plane 702 shares two sides with two other planes 702 and has two open ended sides.

A memory device includes a memory controller and a memory array including, for examples, a number of individual memory die (e.g., die 708). In other words, the die 708 with at least one on-chip inductor 704 is used in a memory device, according to some examples. Such a memory device can be used in various electronic devices.

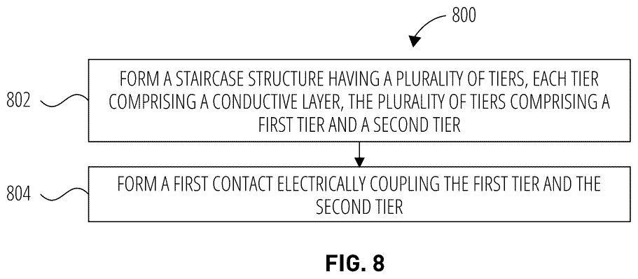

FIG. 8 is a flow diagram of features of an example method 800 of forming an inductor, according to some examples. At 802, a staircase structure is formed, the staircase structure having a plurality of tiers where each tier comprises a conductive layer. The plurality of tiers includes at least a first tier and a second tier. According to some examples, the plurality of tiers forms respective steps on a first side of the staircase structure. The staircase structure is formed, for example, by depositing alternating layers of an oxide and a nitride on a substrate. The alternating layers of oxide and nitride are etched on a first side to form a stepped structure. According to some examples, the etching of the stepped structure is performed using a pull-back etch process. The nitride is etched away, and the vacancies left by the nitride are backfilled with a conductive material. According to some examples, the backfilled conductive material forms the conductive layer of each tier of the plurality of tiers.

At 804, a first contact is formed, the first contact electrically coupling the first tier and the second tier. According to some examples, the first contact is formed by forming a first pillar and a second pillar, where the first pillar is electrically coupled to the first tier and the second pillar is electrically coupled to the second tier. Both the first pillar and the second pillar extend toward the top surface of the staircase structure. A contact strap is formed that electrically couples the first pillar to the second pillar, where the contact strap extends across a portion of the top surface of the staircase structure.

According to some examples, the first contact is one of a set of contacts, each contact in the set of contacts providing electrical coupling between tiers of the plurality of tiers. That is, each tier in the plurality of tiers is connected to another tier by a contact in the set of contacts. According to some examples, the first pillar and the second pillar belong to a set of pillars, where each tier in the plurality of tiers is electrically coupled to a pillar in the set of pillars (e.g., on the contact surface of the stepped portion of the respective tier). According to some examples, the contact strap belongs to a set of contact straps. In some examples, each pillar in the set of pillars is electrically coupled to another pillar in the set of pillars via a contact strap in the set of contact straps. According to some examples, each tier in the plurality of tiers is electrically coupled to another tier in the plurality of tiers via a contact strap in the set of contact straps.

Variations of the method 800 or methods similar to the method 800 can include a number of different embodiments that may be combined depending on the application of such methods or the architecture or process flow of an integrated circuit for which such methods are implemented. Such methods can include inductors such as inductor 500 or inductor 600 or a combination thereof, according to some examples.

Variations of the method 800 or methods similar to the method 800 can include, for example, inclusion of a magnetic core. According to some examples, the staircase structure is etched to form a hole extending through multiple layers of the staircase structure. For example, the hole is laterally spaced from the tiers at the first side of the staircase structure. An oxide layer is deposited around the interior of the hole and the hole is filled with a ferromagnetic material to form a magnetic core, according to some examples. According to some examples, the method 800 excludes the magnetic core and the inductor may have an air core.

Variations of the method 800 or methods similar to the method 800 can include, for example, formation of a slit. According to some examples, the staircase structure (or the alternating layers of oxide and nitride) is etched to form a slit that bifurcates the staircase structure. According to some examples, a layer of oxide is deposited around the interior of the slit and the slit is filled with a ferromagnetic material to form a magnetic core. According to some examples, the slit is backfilled with an oxide.

The method 800 can be used to form an inductor designed to have a desired number of tiers in the staircase structure. Additionally, or alternatively, the method 800 can be used to form an inductor with a desired position of consecutive or non-consecutive tiers within the staircase structure, according to some examples. The method 800 can be used to form an inductor designed to have a desired inductance and/or q-factor. For example, designable parameters such as the dimensions (e.g., length, width, height) of the staircase structure, shape and/or dimensions of the contact(s) (e.g., the first contact), inclusion of a magnetic core, and the number of tiers in the staircase structure, among other parameters, can be modified to achieve a desired inductance and/or q-factor.

Electronic devices, such as mobile electronic devices (e.g., smart phones, tablets, etc.), electronic devices for use in automotive applications (e.g., automotive sensors, control units, driver assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Such electronic devices can be broken down into several main components: a processor (e.g., a central processing unit (CPU) or other main processor); memory (e.g., one or more volatile or nonvolatile memory device, such as DRAM, mobile or low-power double-data-rate synchronous DRAM (DDR SDRAM), etc.); and a storage device (e.g., non-volatile memory (NVM) device, such as flash memory (e.g., 3D NAND flash), ROM, a solid-state drive (SSD), or other memory card structure or assembly, etc.). In certain examples, electronic devices can include a user interface (e.g., a display, touchscreen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

Reference throughout this specification to “one embodiment” or “an embodiment” means that a particular feature, structure, or characteristic described in connection with the embodiment is included in at least one embodiment of claimed subject matter. Thus, the appearances of the phrase “in one embodiment” or “an embodiment” in various places throughout this specification are not necessarily all referring to the same embodiment. Furthermore, the particular features, structures, or characteristics may be combined in one or more embodiments.

To better illustrate the inductor structures and formation or fabrication techniques described herein, a non-limiting set of Example embodiments are set forth below as numerically identified Examples.

Example 1 is an apparatus comprising: a memory sub-component comprising at least one three-dimensional (3D) NAND memory component, the at least one 3D NAND memory component comprising a plurality of memory cells and occupying a first portion of a die; an inductor occupying a second portion of the die, the inductor comprising: a staircase structure having a plurality of tiers, each tier comprising a conductive layer, the plurality of tiers forming respective steps on a first side of the staircase structure, the plurality of tiers comprising a first tier and a second tier, wherein the first tier and the second tier correspond to adjacent steps of the staircase structure; and a first contact electrically coupling the first tier and the second tier

Example 2 is the apparatus of Example 1, wherein the first contact comprises: a first pillar electrically coupled to the first tier of the staircase structure and extending toward a top surface of the staircase structure; a second pillar electrically coupled to the second tier of the staircase structure and extending toward the top surface of the staircase structure; and a contact strap electrically coupling the first pillar to the second pillar, wherein the strap extends across a portion of the top surface of the staircase structure.

Example 3 is the apparatus of Example 2, wherein the contact strap comprises a non-linear-shaped conductor and is one of Z-shaped or S-shaped.

Example 4 is the apparatus of Example 1, wherein each tier in the staircase structure further comprises an insulative layer, wherein the insulative layer is interposed between respective conductive layers of adjacent tiers.

Example 5 is the apparatus of Example 1, wherein the inductor comprises a plurality of contacts electrically coupling respective conductive layers of pairs of adjacent tiers.

Example 6 is the apparatus of Example 1, wherein the inductor further comprises: a hole extending through multiple layers of the staircase structure and laterally spaced from the tiers at the first side of the staircase structure; and a magnetic core occupying at least a portion of the hole and adjacent to multiple layers of the staircase structure.

Example 7 is the apparatus of Example 6, comprising an oxide layer interposed between the magnetic core and the layers comprising the staircase structure.

Example 8 is the apparatus of Example 6, wherein the staircase structure has a slit that bifurcates the staircase structure perpendicular to an ascension direction of the steps.

Example 9 is the apparatus of Example 8, wherein at least a portion of the first contact spans a width of the slit.

Example 10 is the apparatus of Example 8, wherein the first tier is on a first side of the slit and the second tier is on a second side of the slit.

Example 11 is the apparatus of Example 1, wherein the staircase structure has two-hundred thirty-two (232) tiers.

Example 12 is a method of forming an on-chip inductor, the method comprising: forming a staircase structure having a plurality of tiers, each tier comprising a conductive layer, the plurality of tiers forming respective steps on a first side of the staircase structure, the plurality of tiers comprising a first tier and a second tier, wherein the first tier and the second tier correspond to adjacent steps of the staircase structure; and forming a first contact electrically coupling the first tier and the second tier.

Example 13 is the method of Example 12, wherein forming the staircase structure further comprises: depositing alternating layers of an oxide and a nitride on a substrate; etching a stepped structure into a first side of the alternating layers of the oxide and the nitride; etching away the nitride layers; and backfilling the vacancies left by the nitride layers with a conductive material, set.

Example 14 is the method of Example 13, wherein etching the stepped structure into the first side of the alternating layers includes using a pull-back etch process.

Example 15 is the method of Example 12, further comprising: etching the staircase structure to form a hole extending through multiple layers of the staircase structure and laterally spaced from the tiers at the first side of the staircase structure; depositing a layer of oxide around the interior of the hole; and filling the hole with a ferromagnetic material to form a magnetic core.

Example 16 is the method of Example 12, further comprising: etching the staircase structure to form a slit that bifurcates the staircase structure.

Example 17 is the method of Example 16, wherein at least a portion of the first contact spans a width of the slit.

Example 18 is the method of Example 12, wherein forming the first contact further comprises: forming a first pillar electrically coupled to the first tier and extending toward a top surface of the staircase structure; forming a second pillar electrically coupled to the second tier and extending toward the top surface of the staircase structure; and forming a contact strap electrically coupling the first pillar to the second pillar, wherein the contact strap extends across a portion of the top surface of the staircase structure.

Example 19 is the method of Example 18, wherein forming the contact strap includes forming a non-linear-shaped Z-shaped conductor or S-shaped conductor.

Example 20 is an integrated circuit (IC)-based inductor comprising: a staircase structure having a plurality of tiers, each tier comprising a respective conductive layer, the plurality of tiers forming respective steps on a first side of the staircase structure, the plurality of tiers comprising a first tier, a second tier, and a third tier, wherein the second tier is interposed between the first and third tiers; a first pillar electrically coupled to the first tier of the staircase structure and extending toward a top surface of the staircase structure; a second and third pillars electrically coupled to respective portions of the second tier of the staircase structure, wherein the second and third pillars extend toward the top surface of the staircase structure; a fourth pillar electrically coupled to the third tier of the staircase structure and extending toward the top surface of the staircase structure; a first contact strap electrically coupling the first pillar to the second pillar, wherein the first contact strap extends across a first portion of the top surface of the staircase structure; and a second contact strap electrically coupling the third pillar to the fourth pillar, wherein the second contact strap extends across a second portion of the top surface of the staircase structure; wherein the inductor comprises a continuous electrical signal path that extends around a hole in the staircase structure and couples, in turn, the conductive layer of the first tier, the first pillar, the first contact strap, the second pillar, the conductive layer of the second tier, the third pillar, the second contact strap, the fourth pillar, and the conductive layer of the third tier.

Example 21 is an apparatus comprising means to implement of any of Examples 1-20.

Example 22 is a system to implement of any of Examples 1-20.

Example 23 is a method to implement of any of Examples 1-11 or Example 20.

Each of these non-limiting examples can stand on its own or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An apparatus comprising:
a memory sub-component comprising at least one three-dimensional (3D) NAND memory component, the at least one 3D NAND memory component comprising a plurality of memory cells and occupying a first portion of a die;
an inductor occupying a second portion of the die, the inductor comprising:
a staircase structure having a plurality of tiers, each tier comprising a conductive layer, the plurality of tiers forming respective steps on a first side of the staircase structure, the plurality of tiers comprising a first tier and a second tier, wherein the first tier and the second tier correspond to adjacent steps of the staircase structure; and
a first contact electrically coupling the first tier and the second tier.

2. The apparatus of claim 1, wherein the first contact comprises:
a first pillar electrically coupled to the first tier of the staircase structure and extending toward a top surface of the staircase structure;
a second pillar electrically coupled to the second tier of the staircase structure and extending toward the top surface of the staircase structure; and
a contact strap electrically coupling the first pillar to the second pillar, wherein the strap extends across a portion of the top surface of the staircase structure.

3. The apparatus of claim 2, wherein the contact strap comprises a non-linear-shaped conductor and is one of Z-shaped or S-shaped.

4. The apparatus of claim 1, wherein each tier in the staircase structure further comprises an insulative layer, wherein the insulative layer is interposed between respective conductive layers of adjacent tiers.

5. The apparatus of claim 1, wherein the inductor comprises a plurality of contacts electrically coupling respective conductive layers of pairs of adjacent tiers.

6. The apparatus of claim 1, wherein the inductor further comprises:
a hole extending through multiple layers of the staircase structure and laterally spaced from the tiers at the first side of the staircase structure; and
a magnetic core occupying at least a portion of the hole and adjacent to multiple layers of the staircase structure.

7. The apparatus of claim 6, comprising an oxide layer interposed between the magnetic core and the layers comprising the staircase structure.

8. The apparatus of claim 6, wherein the staircase structure has a slit that bifurcates the staircase structure perpendicular to an ascension direction of the steps.

9. The apparatus of claim 8, wherein at least a portion of the first contact spans a width of the slit.

10. The apparatus of claim 8, wherein the first tier is on a first side of the slit and the second tier is on a second side of the slit.

11. The apparatus of claim 1, wherein the staircase structure has two-hundred thirty-two (232) tiers.

12. A method of forming an on-chip inductor, the method comprising:
forming a staircase structure having a plurality of tiers, each tier comprising a conductive layer, the plurality of tiers forming respective steps on a first side of the staircase structure, the plurality of tiers comprising a first tier and a second tier, wherein the first tier and the second tier correspond to adjacent steps of the staircase structure; and
forming a first contact electrically coupling the first tier and the second tier.

13. The method of claim 12, wherein forming the staircase structure further comprises:
depositing alternating layers of an oxide and a nitride on a substrate;
etching a stepped structure into a first side of the alternating layers of the oxide and the nitride;
etching away the nitride layers; and
backfilling the vacancies left by the nitride layers with a conductive material, set.

14. The method of claim 13, wherein etching the stepped structure into the first side of the alternating layers includes using a pull-back etch process.

15. The method of claim 12, further comprising:
etching the staircase structure to form a hole extending through multiple layers of the staircase structure and laterally spaced from the tiers at the first side of the staircase structure;
depositing a layer of oxide around the interior of the hole; and
filling the hole with a ferromagnetic material to form a magnetic core.

16. The method of claim 12, further comprising:
etching the staircase structure to form a slit that bifurcates the staircase structure.

17. The method of claim 16, wherein at least a portion of the first contact spans a width of the slit.

18. The method of claim 12, wherein forming the first contact further comprises:
forming a first pillar electrically coupled to the first tier and extending toward a top surface of the staircase structure;
forming a second pillar electrically coupled to the second tier and extending toward the top surface of the staircase structure; and
forming a contact strap electrically coupling the first pillar to the second pillar, wherein the contact strap extends across a portion of the top surface of the staircase structure.

19. The method of claim 18, wherein forming the contact strap includes forming a non-linear-shaped Z-shaped conductor or S-shaped conductor.

20. An integrated circuit (IC)-based inductor comprising:
a staircase structure having a plurality of tiers, each tier comprising a respective conductive layer, the plurality of tiers forming respective steps on a first side of the staircase structure, the plurality of tiers comprising a first tier, a second tier, and a third tier, wherein the second tier is interposed between the first and third tiers;
a first pillar electrically coupled to the first tier of the staircase structure and extending toward a top surface of the staircase structure;
a second and third pillars electrically coupled to respective portions of the second tier of the staircase structure, wherein the second and third pillars extend toward the top surface of the staircase structure;
a fourth pillar electrically coupled to the third tier of the staircase structure and extending toward the top surface of the staircase structure;
a first contact strap electrically coupling the first pillar to the second pillar, wherein the first contact strap extends across a first portion of the top surface of the staircase structure; and
a second contact strap electrically coupling the third pillar to the fourth pillar, wherein the second contact strap extends across a second portion of the top surface of the staircase structure;
wherein the inductor comprises a continuous electrical signal path that extends around a hole in the staircase structure and couples, in turn, the conductive layer of the first tier, the first pillar, the first contact strap, the second pillar, the conductive layer of the second tier, the third pillar, the second contact strap, the fourth pillar, and the conductive layer of the third tier.
